(19) United States
(12) Patent Application Publication
(10) Pub. No.: US 2020/0176480 A1
(43) Pub. Date: Jun. 4, 2020

(54) DISPLAY PANEL AND DISPLAY DEVICE

(71) Applicants: HKC Corporation Limited, Shenzhen, Guangdong (CN); Chongqing HKC Optoelectronics Technology Co., Ltd., Chongqing (CN)

(72) Inventor: YU-JEN CHEN, Chongqing, (CN)

(21) Appl. No.: 16/619,191

(22) PCT Filed: Jul. 3, 2017
(86) PCT No.: PCT/CN2017/091473

§ 371 Date: Dec. 4, 2019

(30) Foreign Application Priority Data
Jun. 6, 2017 (CN) 201710419481.3

(51) Int. Cl. H01L 27/12; G02F 1/1368; G02F 1/1345; G02F 1/1362

(52) U.S. Cl. CPC H01L 27/124; G02F 1/1368; G02F 1/136286; H01L 27/1255; G02F 1/13452

(57) ABSTRACT

A display panel and a display device are disclosed. The display panel comprises a substrate, pixel regions formed on the substrate, active switches signal coupled to the pixel regions a driving chip disposed on the substrate, and a plurality of signal lines disposed on the substrate and electrically connected to the active switches and coupled to the driving chip through a plurality of sets of wires. Each set of the wires comprises a first wire and a second wire. The display panel further comprises a plurality of metal layers, which are disposed at different planes. The first wire and the second wire are formed by connections of the metal layers.

### BACKGROUND

### Technical Field

This disclosure relates to a technical field of a display, and more particularly to a display panel and a display device.

### Related Art

In a liquid crystal display (LCD), a liquid crystal cell is disposed between two parallel glass substrates, thin film transistors (TFTs) are disposed on the lower glass substrate, and color filters are disposed on the upper glass substrate. The orientations of the liquid crystal molecules are controlled by the changes of the signals and voltages of the TFTs, such that emission of the polarized light from each pixel is also controlled and the objective of display is also achieved.

In view of the structure of the LCD, the LCD display screen adopted in either a laptop or desktop system has a layered structure constituted by different parts. The LCD has two glass plates with thickness of about 1 mm. The two glass plates are spaced by a 5 μm gap homogeneously filled with a liquid crystal material. Because the liquid crystal material itself does not emit light, light sources, such as lamps, are disposed on two sides of the display screen. A backlight plate (or a diffusion plate) and a reflective film are disposed on the backside of the LCD screen. The backlight plate is composed of fluorescent substances and capable of emitting light, and mainly functions to provide a uniform backlight.

The LCD technology also has weakness and technical bottleneck. A LCD and a CRT display are significantly different in the brightness, graphic uniformity, viewable angle and response time. The response time and the viewable angle depend on the quality of the display panel, and the graphic uniformity significantly relates to the auxiliary optical module.

For the LCD, the brightness often relates to its backplate light source. As the light emitted from the backplate light source becomes brighter, the overall brightness of the LCD is increased accordingly. The signal response time is the time lag of the response of the liquid crystal unit of the LCD, and actually represents the time required for the liquid crystal unit to switch from one molecular orientation to another molecular orientation, and the response time is better as it gets shorter. The response time represents the speed of each pixel point of the LCD responding to the input signal (i.e., the speed of the display to transit from dark to light or from light to dark). A short response time means that the user will not be easy to see smear images around fast moving objects upon watching moving images.

A thin film transistor liquid crystal display (TFT-LCD) is one of the main products of the current flat displays, and has become an important display platform in the modern IT and video products. Regarding the main driving principle of the TFT-LCD, the mainboard of the system connects the three-color (R/G/B) compression signal, the control signal and the power to the connectors on the printed circuit board (PCB board) through wires. Data is processed by the timing controller (TCON) IC on the PCB board, and then connected to the display region through the PCB board and through the source-chip on film (S-COF) and the gate-chip on film (G-COF), so that the LCD obtains the required power and signal(s).

Wiring plays a decisive role in the panel design process. Large size display panels have different indicator requirements on wirings from middle-size and small-size display panels. For small screen panels, a reasonable wiring layout can reduce the area occupied by the bezel of the panel and effectively increase the availability of the glass substrate. More particularly, thin bezel panel technology conquers the world at present, and the required size of the bezel of the panel is better as it gets thinner. For large screen panels, wiring layout has to ensure that thousands of IC signals can arrive at the pixel array port on time, otherwise the panel cannot normally display the image. The most important factor that may cause the signal delay is whether the resistance values of the connection wires are highly consistent.

The major difficulty of the equal-resistance wiring method resides in how to modify the wiring in a limited space to adjust the resistance values of different connection wires. For the wiring of a small screen display where the space resource is considered much more, the most optimal layout between ports often realized by wiring at a predetermined bending angles under the criteria of satisfying certain wiring widths and gaps. For the wiring of a large size display panel which have to save the space as much as possible, additional measures also have to be adopted to satisfy the criterion that each wire has the same resistance.

In a large size panel, the wires are mainly connected to the pixel array and the IC port, and the two rows of ports ordinarily have different port gaps (i.e., the pitch). Thus, the overall trend of wiring starts from one end of a smaller pitch to the other end with the larger pitch in a fan-shaped open distribution (fanout).

As the resolution of the display screen increases, the number of signal lines becomes larger, so that the height of the fanout region gets greater. In addition, in view of the product requirement, the bezel is going to be designed thinner and thinner. Thus, it may cause a problem that the height of the fanout region is too large. In addition, according to the modern wiring method, shortening the distance between the signal lines makes the coupling capacitance become too large.

### SUMMARY

The technical problem to be solved by this disclosure is to provide a display panel and a display device capable of decreasing a height of the fanout region.

This disclosure provides a display panel which comprises:

a substrate;

pixel regions formed on the substrate;

active switches coupled to the pixel regions;

a driving chip disposed on the substrate;

a plurality of signal lines disposed on the substrate, and electrically connected to the active switches and coupled to the driving chip through a plurality of sets of wires. Each set of the wires comprises a first wire and a second wire. The display panel further comprises a plurality of metal layers, and the metal layers are disposed at different planes. The first wire and the second wire are formed by connections of the plurality of metal layers.

An objective of this disclosure is implemented through the following technical solutions: according to one aspect of this disclosure, this disclosure discloses a display device including a control circuit and the display panel according to the present invention.

This disclosure utilizes an alternating arrangement of layout of two wires and a plurality of metal layers. Compared with the layout of single metal layer, the gap between the metal layers is increased, and it is beneficial to the decreasing of the coupling capacitance between the connection wires, so that the height of the fanout region is reduced.

### BRIEF DESCRIPTION OF THE DRAWINGS

The embodiments will become more fully understood from the detailed description and accompanying drawings, which are given for illustration only, and thus are not limitative of the present invention, and wherein:

FIG. 1 is a schematic view showing wires of one metal layer in the display panel according to the embodiment of this disclosure;

FIG. 2 is another schematic view showing wires of one metal layer in the display panel according to the embodiment of this disclosure;

FIG. 3 is a schematic view showing a coupling capacitor C1 of one metal layer in the display panel according to the embodiment of this disclosure;

FIG. 4 is a schematic view showing a coupling capacitor C2 of one metal layer in the display panel according to the embodiment of this disclosure;

FIG. 5 is a side view showing two metal layers in the display panel according to the embodiment of this disclosure;

FIG. 6 is a top view showing two metal layers in the display panel according to the embodiment of this disclosure;

FIG. 7 a schematic view showing wires of two metal layers in the display panel according to the embodiment of this disclosure;

FIG. 8 is a schematic view showing alternatively wiring of two metal layers in the display panel according to the embodiment of this disclosure;

FIG. 9 is a top view showing alternatively wiring of two metal layers in the display panel according to the embodiment of this disclosure;

FIG. 10 is a side view showing alternatively wiring of two metal layers in the display panel according to the embodiment of this disclosure;

FIG. 11 is a side view showing wiring of three metal layers in the display panel according to the embodiment of this disclosure;

FIG. 12 is a schematic view showing wiring of three metal layers disposed in parallel and in an overlapped manner in the display panel according to the embodiment of this disclosure;

FIG. 13 is a top view showing wiring of three metal layers disposed in parallel and in an overlapped manner in the display panel according to the embodiment of this disclosure;

FIG. 14 is a side view showing wiring of three metal layers disposed in parallel to and misaligned with one another in the display panel according to the embodiment of this disclosure;

FIG. 15 is a side view showing wiring of three metal layers disposed alternatively in the display panel according to the embodiment of this disclosure;

FIG. 16 is a schematic view showing segmentations of three metal layers in the display panel according to the embodiment of this disclosure;

FIG. 17 is a schematic view showing the first implementation of segmentations of three metal layers in the display panel according to the embodiment of this disclosure;

FIG. 18 is another schematic view showing the first implementation of segmentations of three metal layers in the display panel according to the embodiment of this disclosure;

FIG. 19 is a schematic view showing the second implementation of segmentations of three metal layers in the display panel according to the embodiment of this disclosure;

FIG. 20 is another schematic view showing the second implementation of segmentations of three metal layers in the display panel according to the embodiment of this disclosure;

FIG. 21 is a schematic view showing the third implementation of segmentations of three metal layers in the display panel according to the embodiment of this disclosure;

FIG. 22 is another schematic view showing the third implementation of segmentations of three metal layers in the display panel according to the embodiment of this disclosure; and

FIG. 23 is a schematic structure view showing a display device according to the embodiment of this disclosure.

### DETAILED DESCRIPTION OF INVENTION

Specific structures and function details disclosed herein are only for the illustrative purpose for describing the exemplary embodiment of this disclosure. However, this disclosure can be specifically implemented through many replacements, and should not be explained as being restricted to only the embodiment disclosed herein.

In the description of this disclosure, it is to be understood that the terms “center”, “transversal”, “up,” “down,” “left,” “right,” “vertical”, “horizontal”, “top,” “bottom,” “inside” and “outside” indicating the orientation or position relationships are the orientation or position relationships based on the drawing, are only provided for the purposes of describing this disclosure and simplifying the description, but do not indicate or imply that the directed devices or elements must have the specific orientations or be constructed and operated in the specific orientations, and thus cannot be understood as the restriction to this disclosure. In addition, the terms “first,” and “second” are used for the illustrative purpose only and cannot be understood as indicating or implying the relative importance or implicitly specifying the number of indicated technical features. Therefore, the features restricted by “first” and “second” may expressly or implicitly comprise one or multiple ones of the features. In the description of this disclosure, unless otherwise described, the meaning of “multiple” comprises two or more than two. In addition, the terms “comprises” and any modification thereof intend to cover the non-exclusive inclusions.

In the description of this disclosure, it needs to be appreciated that, unless otherwise expressly stated and limited, the terms “mount,” “link” and “connect” should be interpreted broadly. For example, they may be the fixed connection, may be the detachable connection or may be the integral connection; may be the mechanical connection or may also be the electrical connection; or may be the direct connection, may be the indirect connection through a middle medium or may be the inner communication between two elements. It will be apparent to those skilled in the art that the specific meanings of the above terms in this application may be understood according to the specific conditions.

The terms used herein are for the purpose of describing only specific embodiments and are not intended to limit the exemplary embodiments. Unless the contexts clearly indicate otherwise, the singular form “one,” “a” and “an” used here further intend to include plural forms. It should also be understood that the terms “comprising” and/or “including” are used herein to describe the features to describe the presence of stated features, integers, steps, operations, units and/or elements without excluding the presence or addition of one or more other features, integers, steps, operations, units, elements, and/or combinations thereof.

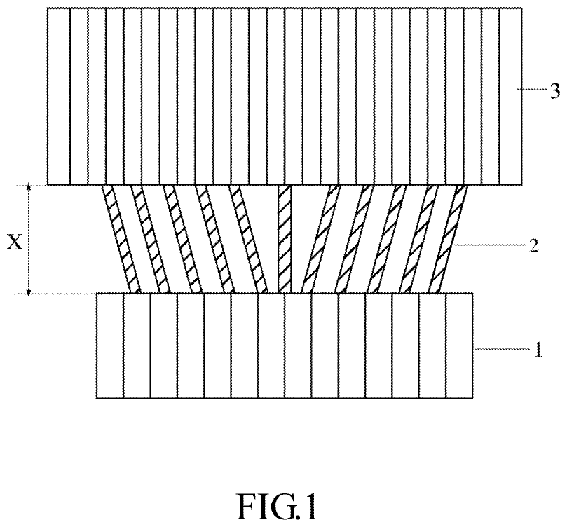

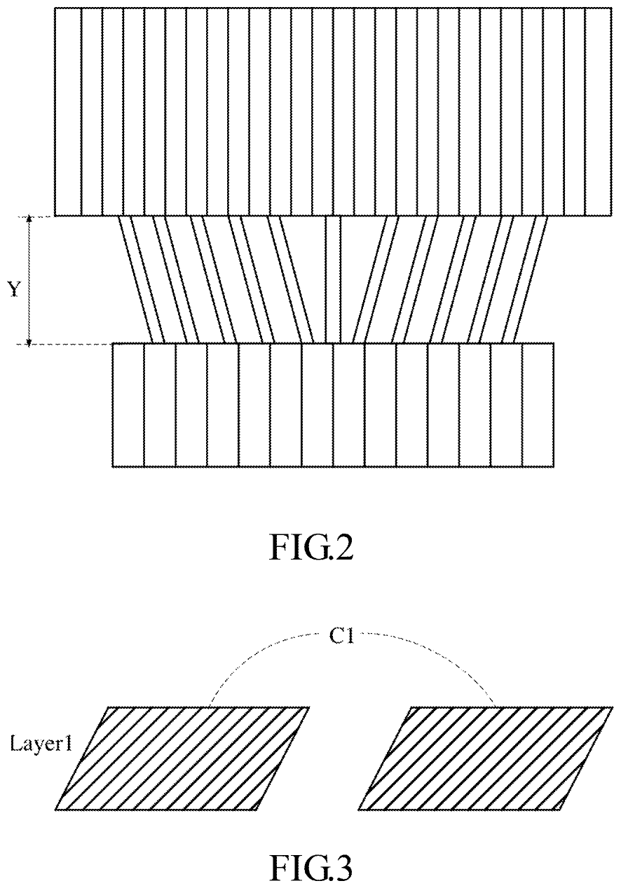

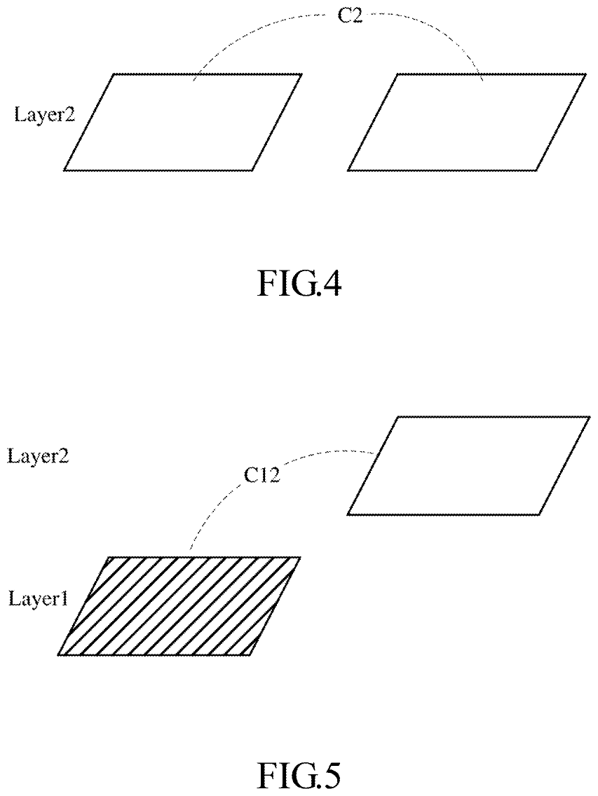

Referring to FIGS. 1 to 4, this embodiment discloses a display panel, which includes a substrate, a driving chip 1 and a plurality of signal lines 3. The substrate includes pixel regions formed on the substrate, and active switches which are coupled to the pixel regions. The driving chip 1 and the signal lines 3 are disposed on the substrate, and the signal lines 3 are electrically connected to the driving chip 1 through wires 2. In the original wiring architecture, it usually uses one metal layer to configure the fanout region, as shown in FIG. 1. In other words, a first wire 21 and a second wire 22 pertain to the same metal layer L1. In the layout design, however, a predetermined gap must be present between the first wire 21 and the second wire 22 so that the first wire 21 and the second wire 22 will not be short-circuited. In addition, if the distance between the first wire 21 and the second wire 22 is too short, then the coupling capacitance may be too large.

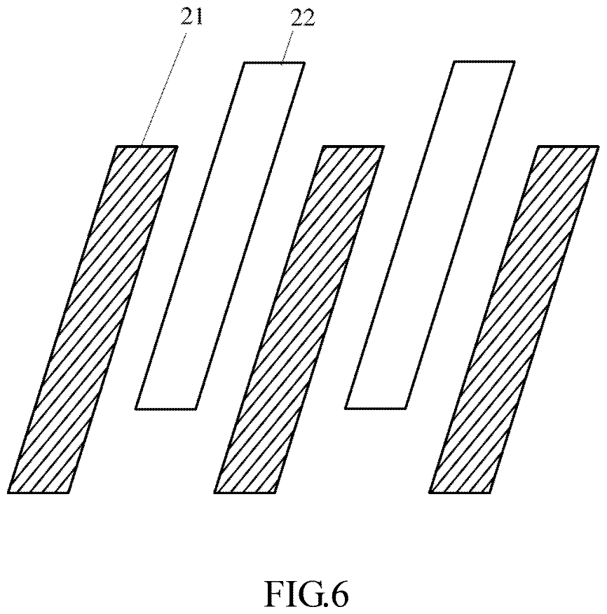

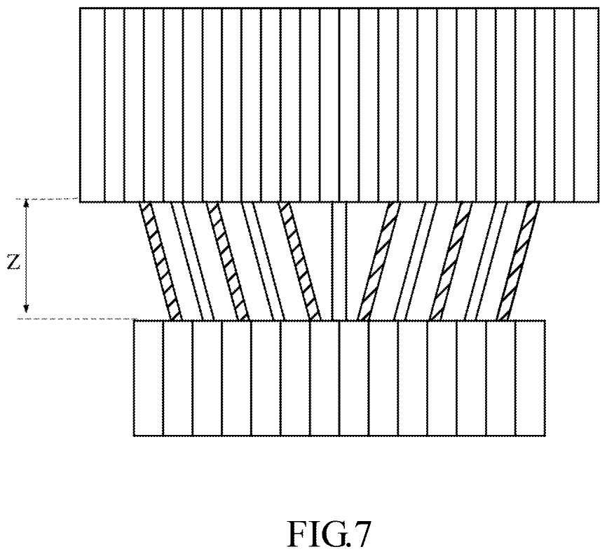

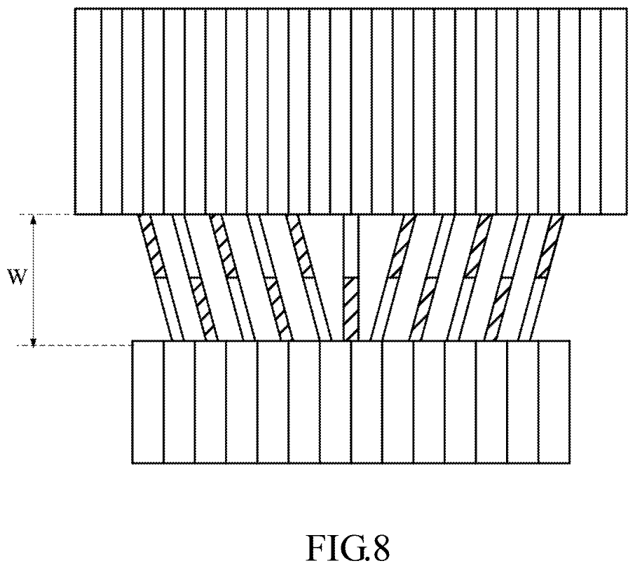

Here, two metal layers (L1, L2) are used for the alternatively wiring configuration of the fanout region, as shown in FIGS. 5 to 7. Such wiring configuration can improve the problem regarding the height of the fanout region, so that the height Z of the fanout region and the height W of the magnetic region are smaller than the height X and the height Y of the fanout region, respectively. However, such wiring architecture may cause a non-uniform distribution of the coupling capacitance between the first wire 21 and the second wire 22.

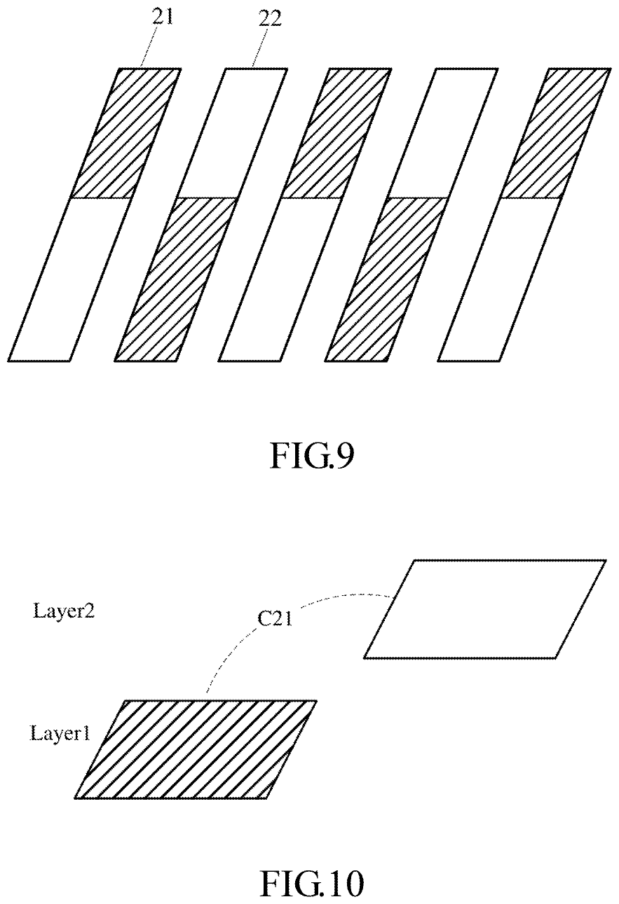

Accordingly, the architecture shown in FIGS. 8 to 10 is further developed. The first wire 21 is half constituted by the first metal layer and half constituted by the second metal layer, while the second connection wire 22 is also half constituted by the second metal layer and half constituted by the first metal layer. Such architecture can make the first wire 21 and the second wire 22 have equal resistance value.

As shown in FIG. 5, the coupling capacitance between the first wire 21 and the second wire 22 is C12. As shown in FIG. 10, the coupling capacitance between the first wire 21 and the second wire 22 is C21. Because the distance between the first metal layer and the second metal layer is relatively longer, the architecture shown in either FIG. 5 or 10 may effectively reduce the coupling capacitance. As the resolution becomes higher, however, the number of the signal lines 3 also increases, and the thin bezel is also an imperative trend at present. So, as shown in FIG. 10 which depicts the wiring layout of the fanout area, the height w of the fanout region is still too large based on the standard required by the current thin bezel architecture.

To this end, the inventor proposes a display panel and a display device based on a three-layered metal structure. The present application will now be described in further detail with reference to the accompanying drawings and preferred embodiments.

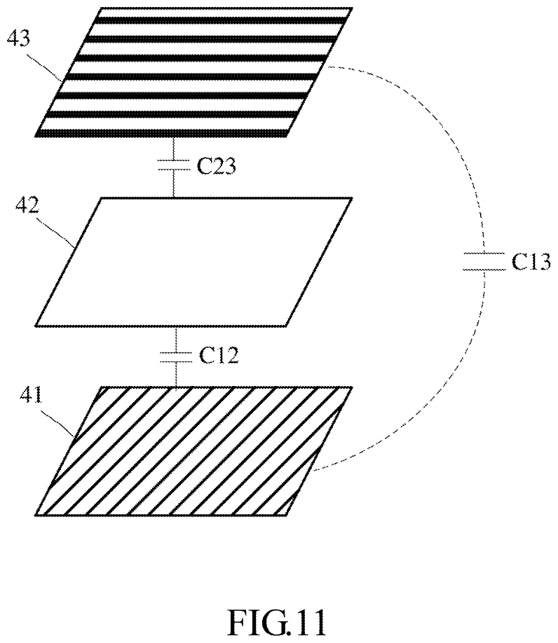

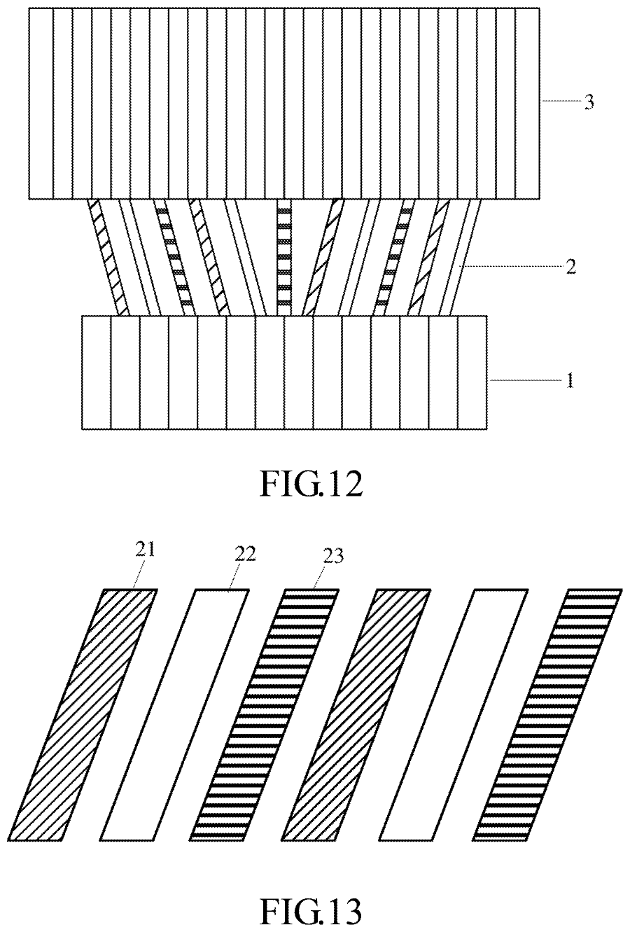

The display panel and the display device according to embodiments of this disclosure will be described with reference to FIGS. 11 to 22.

One embodiment provides a display panel including a substrate, a driving chip 1 and a plurality of signal lines 3. The driving chip 1 is disposed on the substrate. The plurality of signal lines 3 are disposed on the substrate, and electrically connected to the driving chip 1 through a plurality of sets of wires. Each set of wires include a first wire 21, a second wire 22 and a third wire 23. The display panel further includes three metal layers. The three metal layer are disposed at different planes. The first wire 21, the second wire 22 and the third wire 23 are formed by connections of a plurality of metal layers.

This disclosure adopts three wires as one set, and adopts three different layers of metal layers to form the wires, thereby enlarging the gaps between the metal layers. Such configuration is beneficial to the decreasing of the coupling capacitance between the wires. In other words, under the condition of equal coupling capacitance, the horizontal distance between the wires can be moderately reduced, thereby reducing the height of the fanout region.

As a further explanation of the present embodiment, it is understood that C=ε A/d according to the parallel capacitance formula. Two electrodes are required to form a parallel-plate capacitor. So, there are only two metal layers originally. Here, one further metal layer is added, and there are totally three metal layers for the wiring layout of the fanout region, as shown in FIG. 11. From the layered structure shown in FIG. 11, the distance between a first metal layer 41 and a third metal layer 43 is longer, and the constituted capacitor C13 is relatively smaller than C12 and C23. The first metal layer 41 and the third metal layer 43 are overlapped to each other to constitute upper half portion of the fanout region layout of the, and then bridged to the lower half portion. The third metal layer 43 and the first metal layer 41 are overlapped to each other to constitute said lower half portion of the fanout region layout. Then, a second metal layer 42 for separation is disposed at the middle portion. Consequently, the coupling capacitance becomes smaller.

In a further aspect of the embodiment, as shown in FIGS. 12 and 13, the plurality of metal layers are disposed in parallel and in an overlapped manner. The metal layers comprise a first metal layer 41, a second metal layer 42 and a third metal layer 43. The first metal layer 41 constitutes the first wire 21, the second metal layer 42 constitutes the second wire 22, and the third metal layer 43 constitutes the third wire 23.

The plurality of metal layers are disposed in parallel and in an overlapped manner. In other words, the three wires in each set completely coincide with one another. Accordingly, the occupied horizontal space is minimized and the gap between neighboring sets of wires are maximized, so that the coupling capacitance between neighboring sets of wires can be decreased to the maximal extent, and the display effect is enhanced. It should be appreciated that when comparing the capacitor C13 which is constituted by the first metal layer 41 and the third metal layer 43 with the capacitor C12 which is constituted by the first metal layer 41 and the second metal layer 42 and the capacitor C23 which is constituted by the first metal layer 41 and the third metal layer 43, the coupling capacitance C13 is smaller than C12, and C13 is smaller than C23. Consequently, the coupling capacitance is smaller, and the display effect is enhanced.

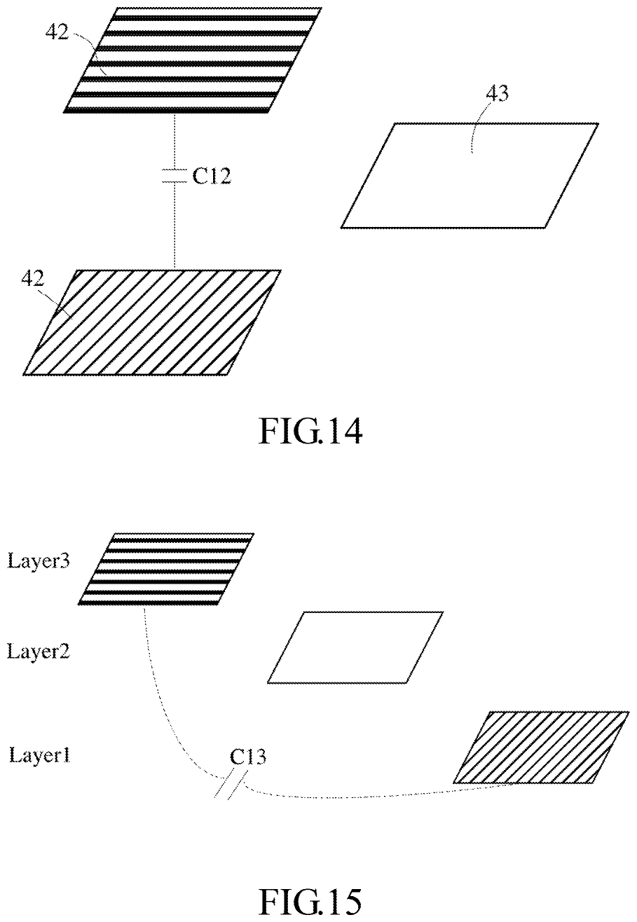

As a further improvement of the present embodiment, as shown in FIG. 14, the metal layers includes the first metal layer 41, the second metal layer 42 and the third metal layer 43 which is disposed between the first metal layer 41 and the second metal layer 42. The first metal layer 41 and the second metal layer 42 are disposed in parallel and in an overlapped manner. The third metal layer 43 is disposed in parallel to and misaligned with the first metal layer 41 and the second metal layer 42. The first metal layer 41 constitutes the first connection wire 21. The second metal layer 42 constitutes the second connection wire 22. The third metal layer 43 constitutes the third connection wire 23.

The first metal layer 41 and the second metal layer 42 are respectively disposed at the upper and lower layers. The coupling capacitance constituted by the first metal layer 41 and the second metal layer 42 is C12. Because the gap between the first metal layer 41 and the second metal layer 42 is relatively larger pre se, the coupling capacitance C12 is smaller. The coupling capacitance C13 constituted by the first metal layer 41 and the third metal layer 43 at the middle position, and the coupling capacitance C23 constituted by the second metal layer 42 and the third metal layer 43 at the middle position have smaller gaps. However, due to the misaligned arrangement, the overlapped area is small, or even there is no overlapped area. Thus, a smaller coupling capacitance may also be obtained. Under the condition of equal coupling capacitance, this embodiment decreases the requirements on the gap between the metal layers. In other words, the vertical stacked height of the substrate can be moderately decreased, and such configuration is beneficial to the decreasing of the thickness of the display panel, and to the satisfaction of the trend of light and slim display panel.

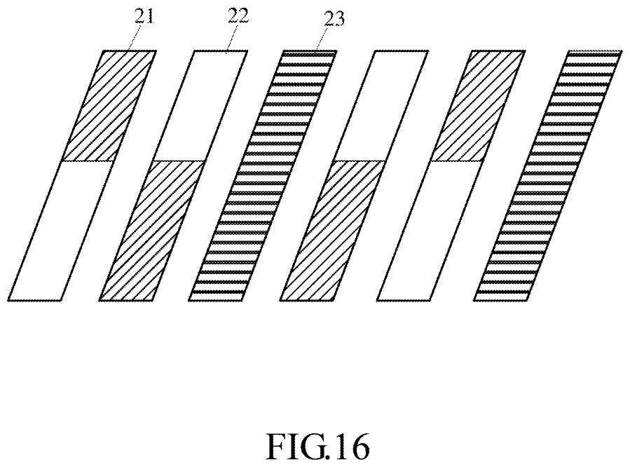

In a further aspect of the embodiment, as shown in FIG. 15, the plurality of metal layers are disposed in parallel and in an overlapped manner. The metal layers comprise a first metal layer 41, a second metal layer 42 and a third metal layer 43. The first metal layer 41 constitutes the first wire 21, the second metal layer 42 constitutes the second wire 22, and the third metal layer 43 constitutes the third wire 23.

Due to the misaligned arrangements between the three metal layers, the overlapped area is small, or even there is no overlapped area. Under the condition of the same gap, a smaller coupling capacitance may also be obtained. Thus, this embodiment decreases the requirements on the gap between the metal layers. In other words, the vertical stacked height of the substrate can be moderately decreased, and it is beneficial to the decreasing of the thickness of the display panel, and to the satisfaction of the trend of light and slim display panel.

In a further aspect of the disclosure, as shown in FIG. 16, the plurality of metal layers are disposed in parallel and in an overlapped manner. Two metal layers are disposed in a segmented manner and electrically connected to each other alternatively to form two of the connection wires. The non-segmented metal layer solely forms the remaining wire.

Due to the misaligned arrangements between the three metal layers, the overlapped area is small, or even there is no overlapped area, so that a smaller coupling capacitance may be obtained. The two wires electrically connected to each other alternatively each include two metal layers that are not at the same layer, so the gap between the metal layers becomes larger, and the coupling capacitance can also be decreased. Thus, this implementation aspect not only reduces the overlap area of the metal layer but also increases the gap between the metal layers, so that a smaller coupling capacitance can be obtained under the condition of the same gap. Thus, using this implementation aspect can decrease the requirement of the gap between the metal layers (i.e., the vertical stacked height of the substrate can be moderately decreased), and such configuration is beneficial to the decreasing of the thickness of the display panel, and to the satisfaction of the trend of light and slim display panel.

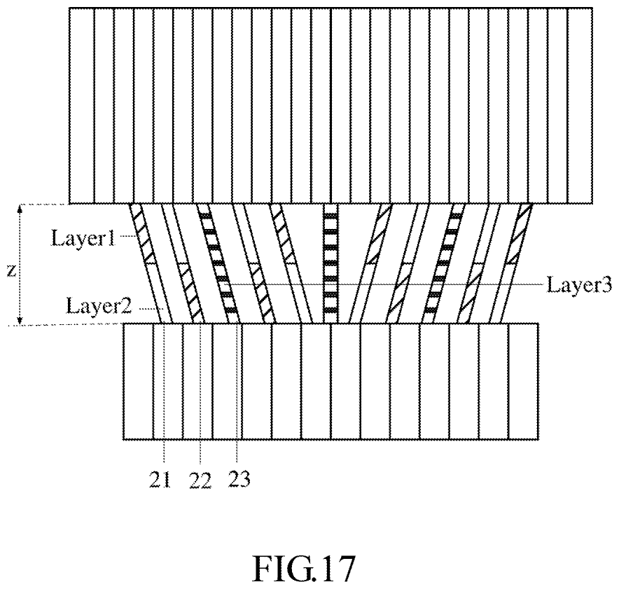

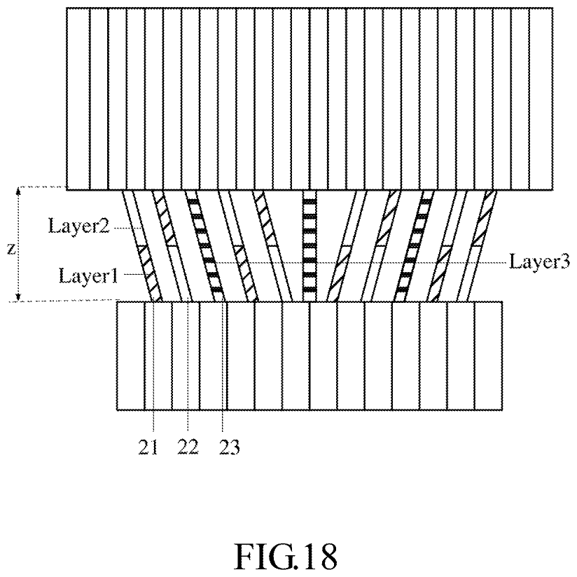

As shown in FIGS. 17 to 18, the display panel of the present embodiment includes a substrate, a driving chip 1 and a plurality of signal lines 3. The driving chip 1 is disposed on the substrate. The plurality of signal lines 3 are disposed on the substrate, and connected to the driving chip 1 through a plurality of sets of wires. Each set of wires include a first wire 21, a second wire 22 and a third wire 23. The display panel further includes three metal layers, which are disposed at different planes. The first wire 21, the second wire 22 and the third wire 23 are formed by connections of a plurality of metal layers. The plurality of metal layers are disposed in parallel to and misaligned with one another. Two metal layers are disposed in a segmented manner, and electrically connected to each other alternatively to form two of the wires. The non-segmented metal layer solely forms the remaining wire. The metal layers comprises a first metal layer 41, a second metal layer 42 and a third metal layer 43. The first metal layer 41 comprises a first connection portion connected to the driving chip 1, and a second connection portion connected to one of the signal lines 3. The second metal layer 42 comprises a third connection portion connected to the driving chip 1, and a fourth connection portion connected to another signal line 3. The first connection portion and the fourth connection portion are electrically connected to each other to constitute the first wire 21, the second connection portion and the third connection portion are electrically connected to each other to constitute the second wire 22, and the third metal layer 43 constitutes the third wire 23.

The abovementioned embodiment is one technical solution regarding to two adjacent wires electrically and alternatively connected to each other. The polarity of the coupling capacitance formed between the first connection portion and the third connection portion is opposite to that of the coupling capacitance formed by the second connection portion and the fourth connection portion, and these two coupling capacitances may offset with each other so as to in turn reduce the effect caused by the coupling capacitances on the connection wires.

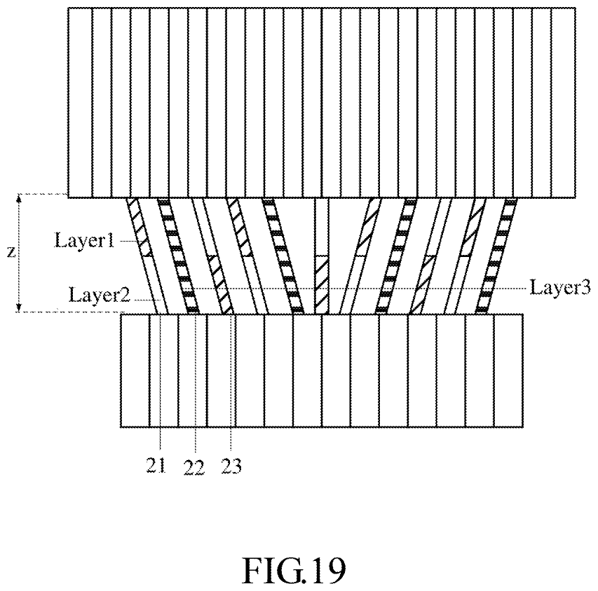

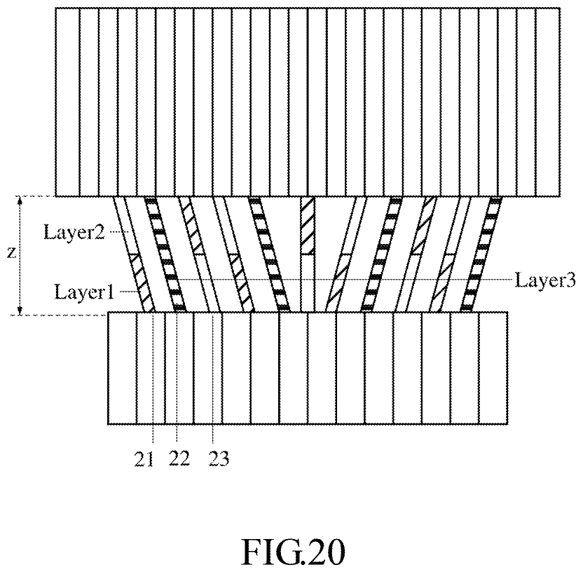

As shown in FIGS. 19 and 20, a display panel of the embodiment comprises a substrate, a driving chip 1 and a plurality of signal lines 3. The driving chip 1 is disposed on the substrate. The plurality of signal lines 3 are disposed on the substrate, and coupled to the driving chip 1 through a plurality of sets of wires. Each set of the wires comprises a first wire 21, a second wire 22 and a third wire 23. The display panel further comprises three metal layers, and these three metal layers are disposed at different planes. The first wire 21, the second wire 22 and the third wire 23 are formed by connections of the plurality of metal layers. The plurality of metal layers are disposed in parallel to and misaligned with one another. Two of the metal layers are disposed in a segmented manner, and electrically connected to each other alternatively to form two of the wires. The non-segmented metal layer solely forms the remaining wire. The metal layers comprise a first metal layer 41, a second metal layer 42 and a third metal layer 43. The first metal layer 41 comprises a first connection portion connected to the driving chip 1, and a second connection portion connected to one of the signal lines 3. The third metal layer 43 comprises a fifth connection portion connected to the driving chip 1, and a sixth connection portion connected to another signal line 3. The first connection portion and the sixth connection portion are electrically connected to each other to constitute the first wire 21. The second connection portion and the fifth connection portion are electrically connected to each other to constitute the third wire 23. The second metal layer 42 constitutes the second wire 22.

The abovementioned embodiment is a technical solution with regard to two separated wires are electrically and alternatively connected to each other. In a horizontal view direction, the second wire 22 is interposed between the first wire 21 and the third connection wire 23 (i.e., the second metal layer 42). The polarity of the coupling capacitance formed between the first connection portion and the second metal layer 42 is opposite to that of the coupling capacitance formed between the fifth connection portion and the second metal layer 42 and these two coupling capacitances may offset with each other. Similarly, the polarity of the coupling capacitance formed between the second connection portion and the second metal layer 42 is opposite to that of the coupling capacitance formed between the sixth connection portion and the second metal layer 42 and these two coupling capacitances may offset with each other, so as to further reduce the effect caused by the coupling capacitances on the connection wires.

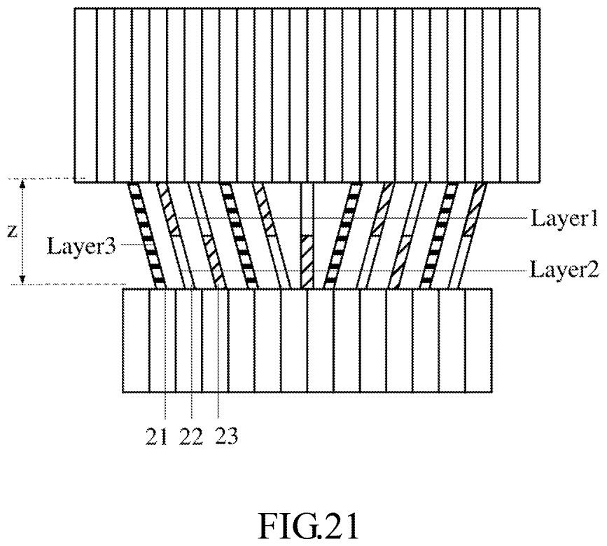

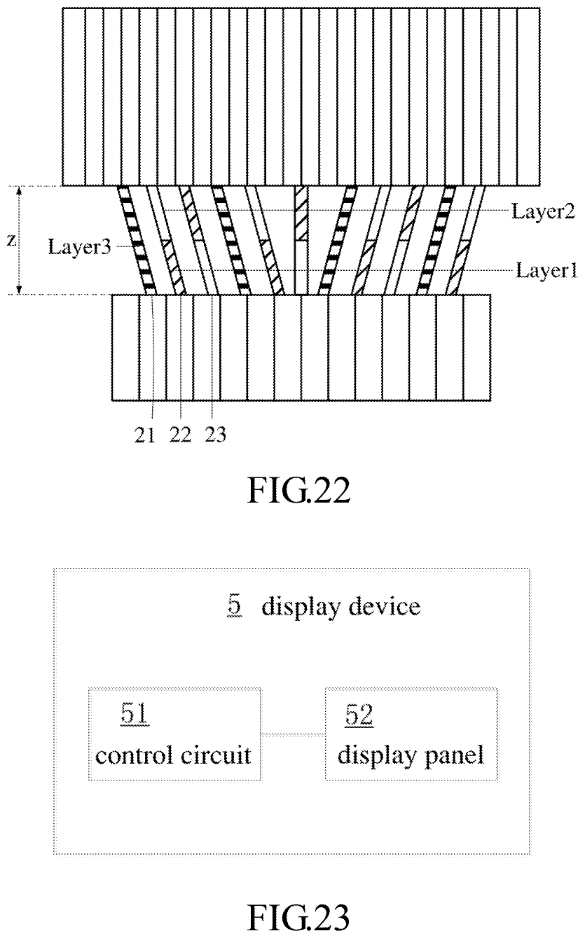

As shown in FIGS. 21 and 22, a display panel according to one embodiment comprises a substrate, a driving chip 1 and a plurality of signal lines 3. The driving chip 1 is disposed on the substrate. The plurality of signal lines 3 are disposed on the substrate, and coupled to the driving chip 1 through a plurality of sets of wires. Each set of the wires comprises a first wire 21, a second wire 22 and a third wire 23. The display panel further comprises three metal layers, and these three metal layers are disposed at different planes. The first wire 21, the second wire 22 and the third wire 23 are formed by connections of the plurality of metal layers. The plurality of metal layers are disposed in parallel to and misaligned with one another. Two of the metal layers are disposed in a segmented manner, and electrically connected to each other alternatively to form two of the wires. The non-segmented metal layer solely forms the remaining wire. The metal layers comprise a first metal layer 41, a second metal layer 42 and a third metal layer 43. The second metal layer 42 comprises a third connection portion connected to the driving chip 1, and a fourth connection portion connected to one of the signal lines 3. The third metal layer 43 comprises a fifth connection portion connected to the driving chip 1, and a sixth connection portion connected to another signal line 3. The third connection portion and the sixth connection portion are electrically connected to each other to constitute the third wire 23. The fourth connection portion and the fifth connection portion are electrically connected to each other to constitute the second wire 22. The first metal layer 41 constitutes the first connection wire 21.

The abovementioned embodiment is a technical solution with regard to two adjacent wires electrically and alternatively connected to each other. The polarity of the coupling capacitance formed between the third connection portion and the fifth connection portion is opposite to that of the coupling capacitance formed by the fourth connection portion and the sixth connection portion, and these two coupling capacitances can offset with each other so as to further reduce the effect caused by the coupling capacitances on the connection wires.

Specifically, in the above-mentioned embodiment, the metal layers are partially overlap, and the overlapping portions are electrically connected via through holes.

The display panel according to the embodiment of the disclosure can be any one type of the following including TN-(Twisted Nematic) type LCD panel or STN-(Super Twisted Nematic) type LCD panel, IPS-(In-Plane Switching) type LCD panel, or VA-(Vertical Alignment) type LCD panel, OLED display panel, QLED display panel, curved panel, and other display panels.

As shown in FIG. 23, in an embodiment of this disclosure, this embodiment discloses a display device 5, and the display device 5 includes a control circuit 51 and a display panel 52 which is electrically coupled to the control circuit 51. The specific structure and connection relationship with respect to the display device 5 in this embodiment can be referred to the display panel 52 in the above-mentioned embodiment with reference to FIGS. 1 to 22. Herein, detailed descriptions of the display device will be omitted.

The display device according to the present embodiment of the disclosure can be an LCD device, an OLED display device, a QLED display device, or other display devices. When the display device according to the present embodiment of the disclosure is an LCD device, it comprises a backlight module serving as the light source for supplying the light with the sufficient luminance and the uniform distribution. The backlight module of this embodiment may be of a front lighting type or a back lighting type. It is to be noted that the backlight module of this embodiment is not restricted thereto.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A display panel, comprising:
a substrate comprising pixel regions and active switches, wherein the pixel regions are formed on the substrate, and the active switches are coupled to the pixel regions;
a driving chip disposed on the substrate; and
a plurality of signal lines disposed on the substrate, wherein the signal lines are electrically connected to the active switches and coupled to the driving chip through a plurality of sets of wires; and each set of the wires comprises a first wire and a second wire, the display panel further comprises a plurality of metal layers, the metal layers are disposed at different planes, and the first wire and the second wire are formed by connections of the plurality of metal layers; and the wires further comprise a third wire, the plurality of metal layers comprise three metal layers, the three metal layers are disposed at different planes, and the first wire, the second wire and the third wire are formed by the connections of the three metal layers; and the plurality of metal layers are disposed in parallel and in a overlapped manner, the metal layers comprise a first metal layer, a second metal layer and a third metal layer, and the first metal layer constitutes the first wire, the second metal layer constitutes the second wire, and the third metal layer constitutes the third wire; and the metal layers comprise a first metal layer, a second metal layer and a third metal layer which is disposed between the first metal layer and the second metal layer, the first metal layer and the second metal layer are disposed in parallel and in a overlapped manner, and the third metal layer are disposed in parallel to and misaligned with the first metal layer and the second metal layer; the first metal layer constitutes the first wire; the second metal layer constitutes the second wire; and the third metal layer constitutes the third wire; and
wherein the plurality of metal layers are disposed in parallel to and misaligned with one another, the metal layers comprise a first metal layer, a second metal layer and a third metal layer, and the first metal layer constitutes the first wire, the second metal layer constitutes the second wire, and the third metal layer constitutes the third wire; and
wherein the plurality of metal layers are disposed in parallel to and misaligned with one another; wherein two metal layers are disposed in a segmented manner and electrically connected to each other to form two of the wires, and the non-segmented metal layer solely forms the remaining one of the wires; and
wherein the metal layers comprise a first metal layer, a second metal layer and a third metal layer; the first metal layer comprises a first connection portion connected to the driving chip, and a second connection portion connected to one of the signal lines, the second metal layer comprises a third connection portion connected to the driving chip, and a fourth connection portion connected to another signal line, the first connection portion and the fourth connection portion are electrically connected to each other to constitute the first wire, the second connection portion and the third connection portion are electrically connected to each other to constitute the second wire, and the third metal layer constitutes the third wire; and
wherein the metal layers comprise a first metal layer, a second metal layer and a third metal layer; the first metal layer comprises a first connection portion connected to the driving chip, and a second connection portion connected to one of the signal lines, the third metal layer comprises a fifth connection portion connected to the driving chip, and a sixth connection portion connected to another signal line, the first connection portion and the sixth connection portion are electrically connected to each other to constitute the first wire, the second connection portion and the fifth connection portion are electrically connected to each other to constitute the second wire, and the second metal layer constitutes the second wire; and
wherein the metal layers comprise a first metal layer, a second metal layer and a third metal layer, the second metal layer comprises a third connection portion connected to the driving chip, and a fourth connection portion connected to one of the signal lines, the third metal layer comprises a fifth connection portion connected to the driving chip, and a sixth connection portion connected to another signal line, the third connection portion and the sixth connection portion are electrically connected to each other to constitute the first wire, the fourth connection portion and the fifth connection portion are electrically connected to each other to constitute the second wire, and the first metal layer constitutes the first wire.

2. A display panel, comprising:
a substrate comprising pixel regions and active switches, wherein the pixel regions are formed on the substrate, and the active switches are coupled to the pixel regions;
a driving chip disposed on the substrate; and
a plurality of signal lines disposed on the substrate, wherein the signal lines are electrically connected to the active switches and coupled to the driving chip through a plurality of sets of wires; wherein each set of the wires comprises a first wire and a second wire, the display panel further comprises a plurality of metal layers, the metal layers are disposed at different planes, and the first wire and the second wire are formed by connections of the plurality of metal layers.

3. The display panel according to claim 2, wherein the wires further comprise a third wire, the plurality of metal layers comprise three metal layers, the three metal layers are disposed at different planes, and the first wire, the second wire and the third wire are formed by the connections of the three metal layers.

4. The display panel according to claim 3, wherein the plurality of metal layers are disposed in parallel and in a overlapped manner, the metal layers comprise a first metal layer, a second metal layer and a third metal layer, and the first metal layer constitutes the first wire, the second metal layer constitutes the second wire, and the third metal layer constitutes the third wire.

5. The display panel according to claim 3, wherein the metal layers comprise a first metal layer, a second metal layer and a third metal layer which is disposed between the first metal layer and the second metal layer, the first metal layer and the second metal layer are disposed in parallel and in a overlapped manner, and the third metal layer is disposed in parallel to and misaligned with the first metal layer and the second metal layer, the first metal layer constitutes the first wire, the second metal layer constitutes the second wire, and the third metal layer constitutes the third wire.

6. The display panel according to claim 3, wherein the plurality of metal layers are disposed in parallel and misaligned with one another, the metal layers comprise a first metal layer, a second metal layer and a third metal layer, and the first metal layer constitutes the first wire, the second metal layer constitutes the second wire, and the third metal layer constitutes the third wire.

7. The display panel according to claim 3, wherein the plurality of metal layers are disposed in parallel and misaligned with one another, and wherein two of the metal layers are disposed in a segmented manner and are electrically and alternately connected to each other to constitute two of the wires, and the non-segmented metal layer solely forms the remaining one wire.

8. The display panel according to claim 7, wherein the metal layers comprise a first metal layer, a second metal layer and a third metal layer, the first metal layer comprises a first connection portion connected to the driving chip and a second connection portion connected to one of the signal lines, the second metal layer comprises a third connection portion connected to the driving chip and a fourth connection portion connected to another signal line, the first connection portion and the fourth connection portion are electrically connected to each other to constitute the first wire, the second connection portion and the third connection portion are electrically connected to each other to constitute the second wire, and the third metal layer constitutes the third wire.

9. The display panel according to claim 7, wherein the metal layers comprise a first metal layer, a second metal layer and a third metal layer, the first metal layer comprises a first connection portion connected to the driving chip and a second connection portion connected to one of the signal lines, the third metal layer comprises a fifth connection portion connected to the driving chip and a sixth connection portion connected to another signal line, the first connection portion and the sixth connection portion are electrically connected to each other to constitute the first wire, the second connection portion and the fifth connection portion are electrically connected to each other to constitute the third wire, and the second metal layer constitutes the second wire.

10. The display panel according to claim 7, wherein the metal layers comprise a first metal layer, a second metal layer and a third metal layer, the second metal layer comprises a third connection portion connected to the driving chip and a fourth connection portion connected to one of the signal lines, the third metal layer comprises a fifth connection portion connected to the driving chip and a sixth connection portion connected to another signal line, the third connection portion and the sixth connection portion are electrically connected to each other to constitute the third wire, the fourth connection portion and the fifth connection portion are electrically connected to each other to constitute the second wire, and the first metal layer constitutes the first wire.

11. A display device, comprising a control circuit and a display panel, wherein the display panel comprises:
a substrate comprising pixel regions and active switches, wherein the pixel regions are formed on the substrate, and the active switches are coupled to the pixel regions;
a driving chip disposed on the substrate, and
a plurality of signal lines disposed on the substrate, wherein the signal lines are electrically connected to the active switches and coupled to the driving chip through a plurality of sets of wires, and each set of the wires comprises a first wire and a second wire, the display panel further comprises a plurality of metal layers, the metal layers are disposed at different planes, and the first wire and the second wire are formed by connections of the plurality of metal layers.

12. The display device according to claim 11, wherein the wires further comprise a third wire, the plurality of metal layers comprise three metal layers, the three metal layers are disposed at different planes, and the first wire, the second wire and the third wire are formed by the connections of the three metal layers.

13. The display panel according to claim 12, wherein the plurality of metal layers are disposed in parallel and in an overlapped manner, the metal layers comprise a first metal layer, a second metal layer and a third metal layer, and the first metal layer constitutes the first wire; the second metal layer constitutes the second wire; and the third metal layer constitutes the third wire.

14. The display device according to claim 12, wherein the metal layers comprise a first metal layer, a second metal layer and a third metal layer which is disposed between the first metal layer and the second metal layer, the first metal layer and the second metal layer are disposed in parallel and in a overlapped manner, and the third metal layer is disposed in parallel to and misaligned with the first metal layer and the second metal layer, the first metal layer constitutes the first wire, the second metal layer constitutes the second wire, and the third metal layer constitutes the third wire.

15. The display device according to claim 12, wherein the plurality of metal layers are disposed in parallel to and misaligned with one another, the metal layers comprise a first metal layer, a second metal layer and a third metal layer, and the first metal layer constitutes the first wire, the second metal layer constitutes the second wire, and the third metal layer constitutes the third wire.

16. The display device according to claim 12, wherein the plurality of metal layers are disposed in parallel to and misaligned with one another, two of the metal layers are disposed in a segmented manner and electrically connected to each other to form two of the connection wires, and the non-segmented metal layer solely forms the remaining one of the wires.

17. The display device according to claim 16, wherein the metal layers comprise a first metal layer, a second metal layer and a third metal layer, the first metal layer comprises a first connection portion connected to the driving chip, and a second connection portion connected to one of the signal lines, the second metal layer comprises a third connection portion connected to the driving chip, and a fourth connection portion connected to another signal line, the first connection portion and the fourth connection portion are electrically connected to each other to constitute the first wire, the second connection portion and the third connection portion are electrically connected to each other to constitute the second wire, and the third metal layer constitutes the third wire.

18. The display device according to claim 16, wherein the metal layers comprise a first metal layer, a second metal layer and a third metal layer; the first metal layer comprises a first connection portion connected to the driving chip, and a second connection portion connected to one of the signal lines, the third metal layer comprises a fifth connection portion connected to the driving chip, and a sixth connection portion connected to another signal line, the first connection portion and the sixth connection portion are electrically connected to each other to constitute the first wire, and the second connection portion and the fifth connection portion are electrically connected to each other to constitute the third wire, and the second metal layer constitutes the second wire.

19. The display device according to claim 16, wherein the metal layers comprise a first metal layer, a second metal layer and a third metal layer, the second metal layer comprises a third connection portion connected to the driving chip, and a fourth connection portion connected to one of the signal lines, the third metal layer comprises a fifth connection portion connected to the driving chip, and a sixth connection portion connected to another signal line, the third connection portion and the sixth connection portion are electrically connected to each other to constitute the third wire, the fourth connection portion and the fifth connection portion are electrically connected to each other to constitute the second wire, and the first metal layer constitutes the first wire.
